(19) United States
(12) Patent Application Publication
(10) Pub. No.: US 2012/0063212 A1
(43) Pub. Date: Mar. 15, 2012

(54) SEMICONDUCTOR DEVICE AND METHOD OF MANUFACTURING THE SAME

(75) Inventors: Masahiko Kanda, Saitama-shi (JP); Koji Miyamoto, Yokohama-shi (JP)

(73) Assignee: KABUSHIKI KAISHA TOSHIBA, Tokyo (JP)

(21) Appl. No.: 13/049,015

(22) Filed: Mar. 16, 2011

(30) Foreign Application Priority Data
Sep. 13, 2010 (JP) 2010-204869

(51) Int. Cl. G11C 11/00; H01L 21/8238; H01L 27/092

(52) U.S. Cl. 365/156; 257/377; 438/213; 257/E27.062; 257/E21.616

(57) ABSTRACT

According to one embodiment, a semiconductor device includes a first transistor and a second transistor having a conductivity type which is different from a conductivity type of the first transistor, the first transistor and the second transistor being disposed on a semiconductor substrate such that a gate electrode of the first transistor and a gate electrode of the second transistor are connected to each other. The gate electrode of the first transistor includes first impurities and second impurities which suppress diffusion of the first impurities, and a concentration peak of the first impurities is formed at a shallower position than a concentration peak of the second impurities.

### CROSS-REFERENCE TO RELATED APPLICATIONS

This application is based upon and claims the benefit of priority from Japanese Patent Application No. 2010-204869, filed Sep. 13, 2010; the entire contents of which are incorporated herein by reference.

### FIELD

Embodiments described herein relate generally to a semiconductor device and a method of manufacturing the same.

### BACKGROUND

An SRAM (Static Random Access Memory), for instance, is known as a semiconductor device which is configured such that a gate electrode of an N-type MOSFET and a gate electrode of a P-type MOSFET are connected to each other.

### BRIEF DESCRIPTION OF THE DRAWINGS

FIG. 1 is a plan view showing a plan-view, structure example of a semiconductor device according to a first embodiment;

FIG. 2 is an equivalent circuit diagram showing a memory cell (SRAM cell) of the semiconductor device according to the first embodiment;

FIG. 3 is a cross-sectional view showing a cross-sectional structure example, taken along line in FIG. 1;

FIG. 4 is a cross-sectional view showing a cross-sectional structure example, taken along line IV-IV in FIG. 1;

FIG. 5 is a cross-sectional view showing a cross-sectional structure example, taken along line V-V in FIG. 1;

FIG. 6 is a graph showing an impurity concentration profile along line VI-VI′ in FIG. 3 and FIG. 5;

FIG. 7 is a cross-sectional view illustrating a fabrication step of the semiconductor device according to the first embodiment;

FIG. 8 is a cross-sectional view illustrating a fabrication step of the semiconductor device according to the first embodiment;

FIG. 9 is a cross-sectional view illustrating a fabrication step of the semiconductor device according to the first embodiment;

FIG. 10 is a cross-sectional view illustrating a fabrication step of a semiconductor device according to a second embodiment;

FIG. 11 is a graph showing an impurity concentration profile along a depth direction of a gate electrode according to a comparative example;

FIG. 12 is a cross-sectional view illustrating a fabrication step of the semiconductor device according to the comparative example; and

FIG. 13 is a table showing conditions for impurity doping in the first and second embodiments and the comparative example.

### DETAILED DESCRIPTION

In general, according to one embodiment, a semiconductor device includes a first transistor and a second transistor having a conductivity type which is different from a conductivity type of the first transistor, the first transistor and the second transistor being disposed on a semiconductor substrate such that a gate electrode of the first transistor and a gate electrode of the second transistor are connected to each other. The gate electrode of the first transistor includes first impurities and second impurities which suppress diffusion of the first impurities, and a concentration peak of the first impurities is formed at a shallower position than a concentration peak of the second impurities.

When a semiconductor device, which is configured such that a gate electrode of an N-type MOSFET and a gate electrode of a P-type MOSFET are connected to each other, is to be fabricated, there is a case in which impurities, such as phosphorus, are doped, for example, in a step (gate pre-doping) of introducing impurities in the gate electrode of the N-type MOSFET. However, in the case of the structure in which the gate electrode of the N-type MOSFET and the gate electrode of the P-type MOSFET are connected to each other, the doped impurities move in the gate electrode and the impurities diffuse into the P-type MOSFET.

As the result of such influence that the impurities are diffused from the N-type MOSFET side to the gate electrode of the P-type MOSFET, there is a tendency that such a disadvantage occurs that the characteristics of the P-type MOSFET become non-uniform and the operation margin of the semiconductor device is degraded.

In the following embodiments, a description is given of a semiconductor device which is advantageous in the improvement of the operation margin, and a method of manufacturing the semiconductor device. In the following embodiments, an SRAM (Static Random Access Memory) is described as an example of the semiconductor device. However, the semiconductor device is not limited to this example. In the description below, common parts are denoted by like reference numerals throughout the drawings.

### First Embodiment

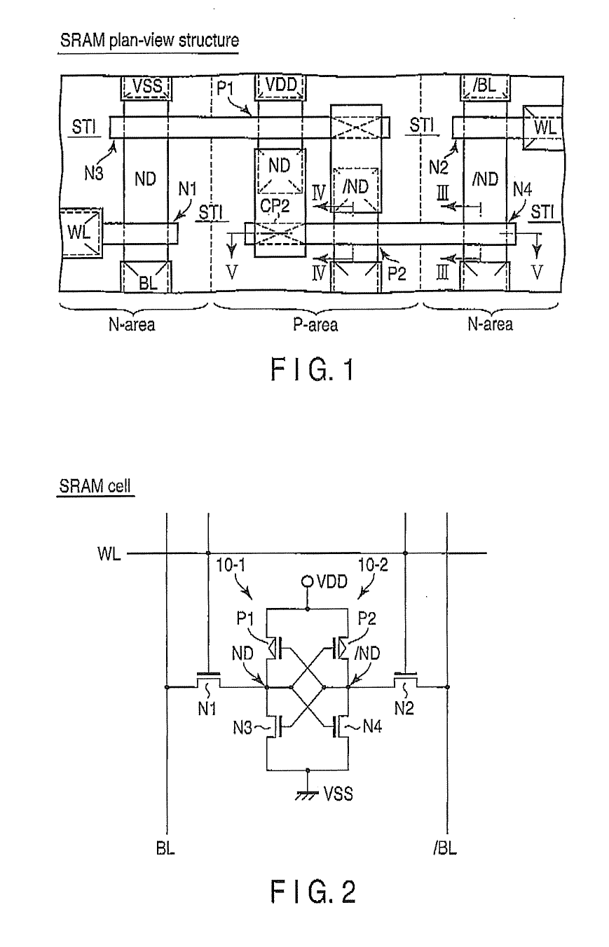

Referring to FIG. 1 to FIG. 9, a semiconductor device according to a first embodiment and a method of manufacturing the semiconductor device are described. In the present embodiment, an SRAM (Static Random Access Memory) is described as an example of the semiconductor device which is configured such that a gate electrode of an N-type MOSFET and a gate electrode of a P-type MOSFET are connected to each other.

### <1. Structure Example>

1-1. Plan-View Structure Example

To begin with, referring to FIG. 1, a plan-view structure example of the semiconductor device according to the first embodiment is described.

As shown in FIG. 1, P-type transistors (P1, P2) are disposed in a P-area of a semiconductor substrate (Si-sub), and N-type transistors (N1 to N4) are disposed in N-areas. In this example, these six transistors constitute a memory cell (SRAM cell) which stores 1-bit data.

As shown in FIG. 1, in this example, the gate electrodes of the N-type transistors (N1 to N4) and the gate electrodes of the P-type transistors (P1, P2) are connected to each other.

1-2. Circuit Structure Example of SRAM Cell

Next, referring to FIG. 2, a structure example of the SRAM cell (SRAM Cell) is described.

As shown in FIG. 2, the SRAM cell is composed of the MOS transistors 21 through N4. The SRAM cell comprises transfer transistors (Transfer Tr) N1 and N2 and inverter circuits 10-1 and 10-2 which are connected in a flip-flop fashion so as to store data.

One end of the current path of the transfer transistor Ni is connected to a bit line BL, the other end of the current path of the transfer transistor N1 is connected to a node ND of the inverter circuit 10-1, and the gate of the transfer transistor N1 is connected to a word line WL. One end of the current path of the transfer transistor N2 is connected to a bit line /BL, the other end of the current path of the transfer transistor N2 is connected to a node /ND of the inverter circuit 10-2, and the gate of the transfer transistor N2 is connected to the word line WL.

The inverter circuit 10-1 comprises a load transistor (Load Tr) P1 and a driver transistor (Driver Tr) N3. One end of the current path of the driver transistor N3 is connected to a ground power supply VSS, the other end of the current path of the driver transistor N3 is connected to one end of the current path of the load transistor P1 at the node ND, and the gate of the driver transistor N3 is connected to the gate of the load transistor P1 and to the node /ND of the inverter circuit 10-2. The other end of the current path of the load transistor P1 is connected to an internal power supply VDD.

The inverter circuit 10-2 comprises a load transistor 22 and a driver transistor N4. One end of the current path of the driver transistor N4 is connected to the ground power supply VSS, the other end of the current path of the driver transistor N4 is connected to one end of the current path of the load transistor P2 at the node /ND, and the gate of the driver transistor N4 is connected to the gate of the load transistor P2 and to the node ND of the inverter circuit 10-1. The other end of the current path of the load transistor P2 is connected to the internal power supply VDD.

1-3. Cross-Sectional Structure Example

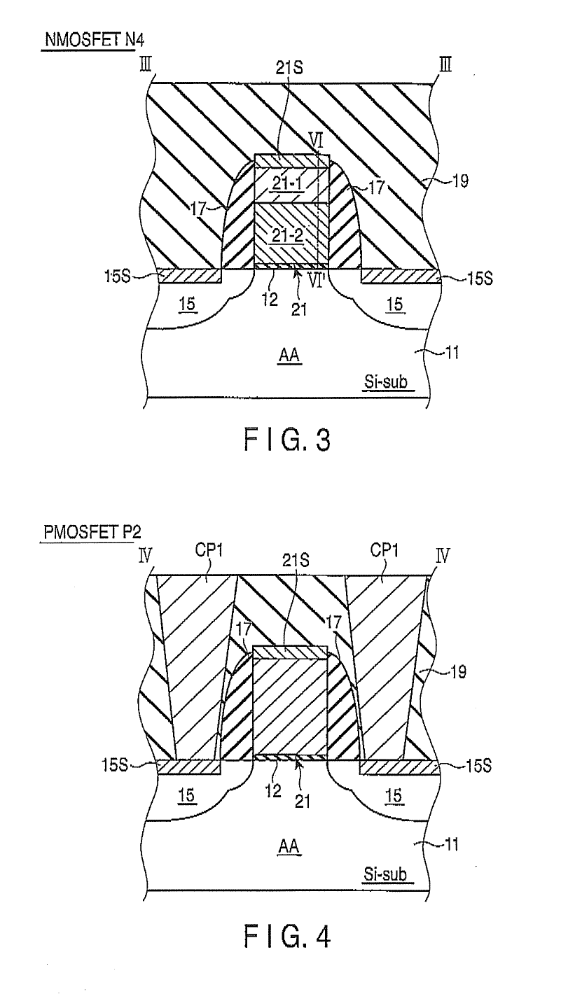

Next, referring to FIG. 3 to FIG. 6, a cross-sectional structure example of the semiconductor device according to the first embodiment is described. In the description below, cross-sectional structures along lines IV-IV and V-V in FIG. 1 are described by way of example.

Re: N-Type Transistor N4

FIG. 3 shows a cross-sectional structure example of the N-type transistor N4.

As shown in FIG. 3, the N-type transistor N4 is disposed in an active area AA of the N-area of the silicon substrate (Si-sub).

The N-type transistor N4 comprises a gate insulation film 12, a gate electrode 21, spacers 17, source/drain diffusion layers 15 and silicide layers 15S and 21S.

The gate insulation film 12 is provided on the silicon substrate 11.

The gate electrode 21 is provided on the gate insulation film 12, and comprises a phosphorus layer 21-1 and a carbon layer 21-2. A description will be given later of a profile of impurity concentration in the gate electrode 21 along line VI-VI′ in FIG. 3.

The phosphorus layer 21-1 is formed by doping in the gate electrode 21 in order to control the ratio of depletion in the gate electrode 21 in the manufacturing process which will be described later.

The carbon layer 21-2 is formed by doping in the gate electrode 21 prior to the doping step of the phosphorus layer 21-1 in the manufacturing process which will be described later, thereby making the gate electrode 21 amorphous and serving as a layer for suppressing diffusion of the phosphorus layer 21-1 into the P-area.

The spacers 17 are provided along the side walls of the gate electrode 21.

The source/drain diffusion layers 15 are provided, spaced apart, on the silicon substrate 11 so as to sandwich the gate electrode 12, and function as a current path at a time of operation.

The silicide layers 15S and 21S are formed by a salicide process which will be described later, and are provided on the source/drain diffusion layers 15 and the gate electrode.

An interlayer insulation film 19 is provided in a manner to cover the N-type transistor N4.

Re: P-Type Transistor P2

FIG. 4 shows a cross-sectional structure example of the P-type transistor P2.

As shown in FIG. 4, the P-type transistor P2 is disposed in an active area AA of the P-area of the silicon substrate (Si-sub).

The gate electrode 21 of the P-type transistor P2, as shown in FIG. 4, differs from that of the N-type transistor N4 in that the gate electrode 21 does not include the phosphorus layer 21-1 or carbon layer 21-2.

In addition, in this example, contact wirings CP1 are provided on the source/drain diffusion layers 15 of the P-type transistor P2.

Re: Cross-Sectional Structure in which Gate Electrodes of N-Type and P-Type Transistors are Mutually Connected

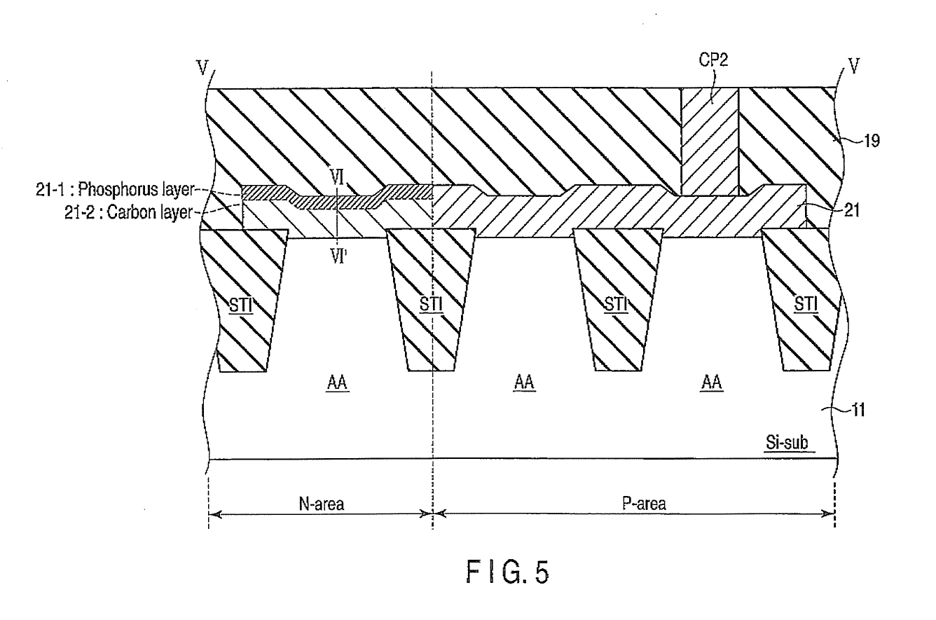

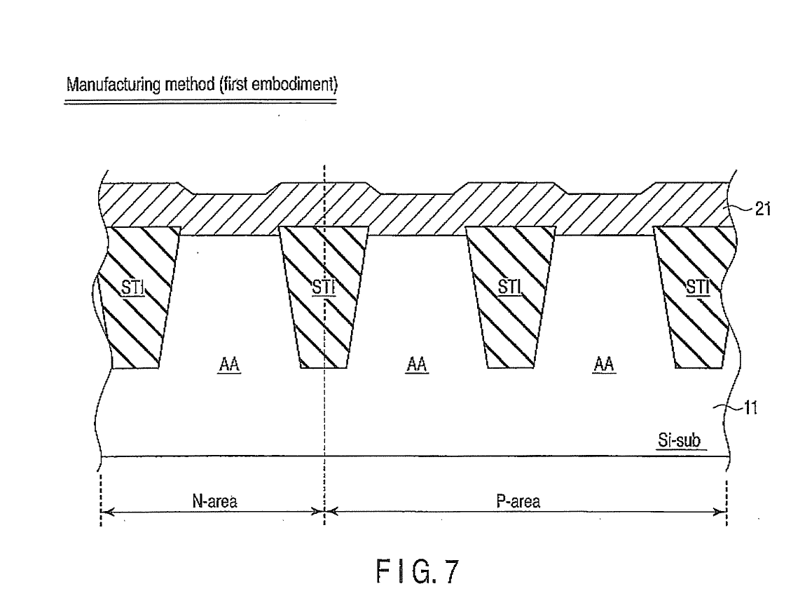

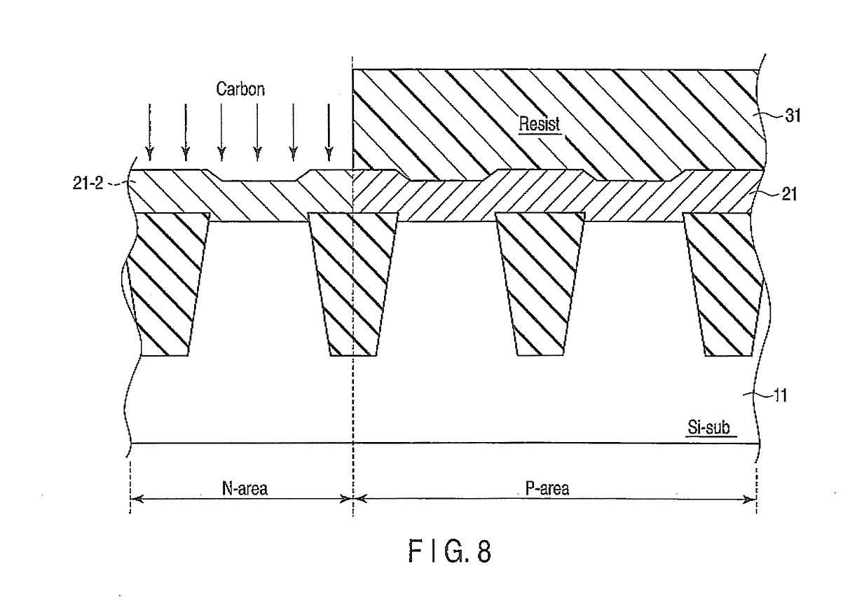

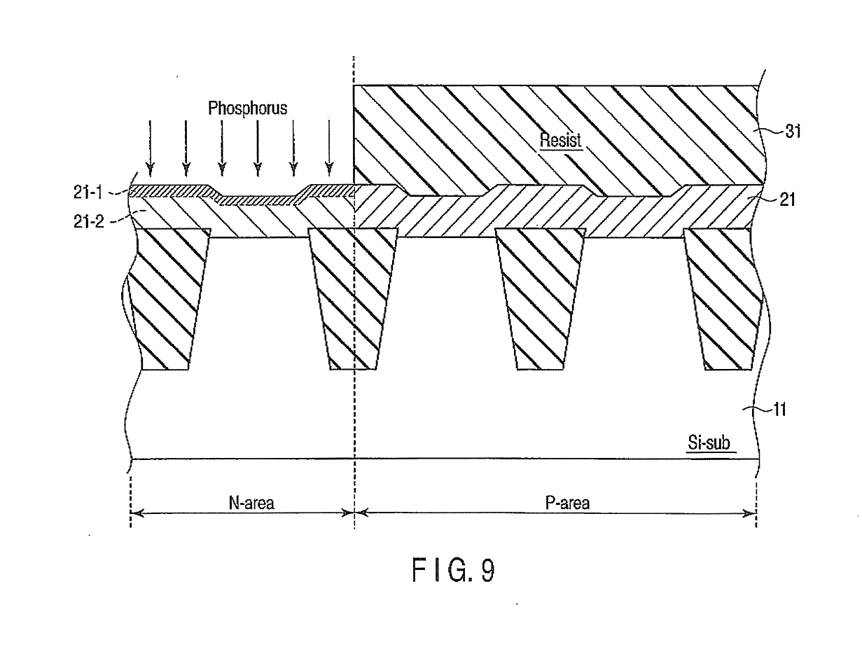

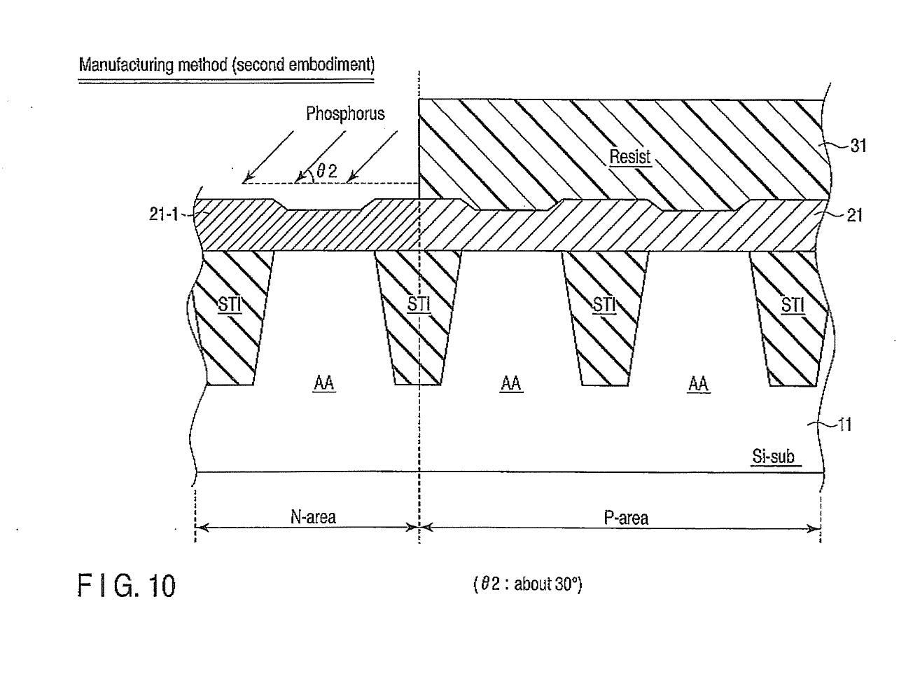

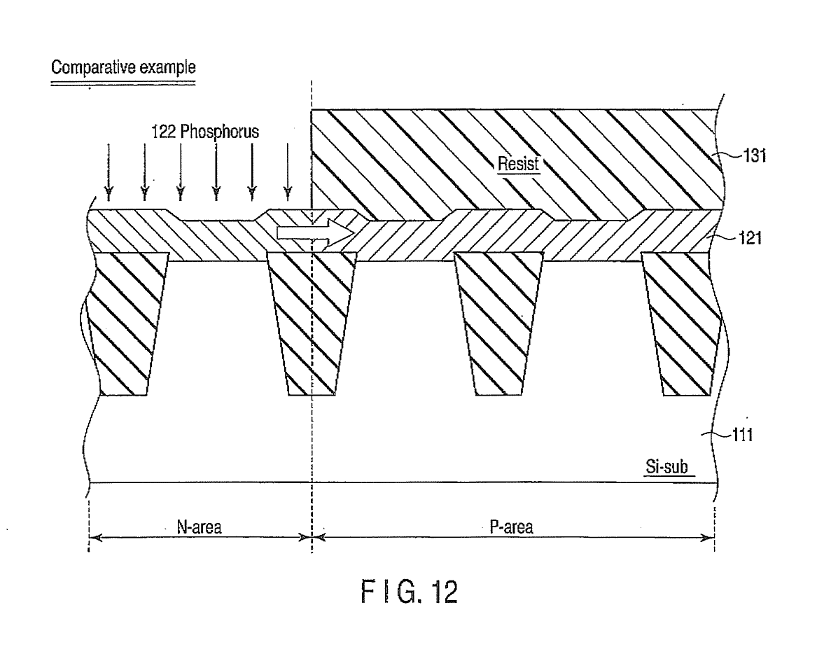

FIG. 5 shows a cross-sectional structure, taken along line V-V in FIG. 1, in which the gate electrode 21 of the N-type transistor N4 and the gate electrode 21 of the P-type transistor P2 are connected to each other. For the purpose of simple description, FIG. 5 omits depiction of the gate insulation film. The same applies to FIG. 7, FIG. 8, FIG. 9, FIG. 10 and FIG. 12.

As shown in FIG. 5, the gate electrode (GC(Poly-Si)) 21 is disposed on device isolation insulation films STI and active areas AA. As described above, the gate electrode 21 comprises the phosphorus layer 21-1 and carbon layer 21-2. A contact wiring CP2 is provided on the gate electrode 21 in the active area AA.

Re: Impurity Concentration Profile in Depth Direction of Gate Electrode

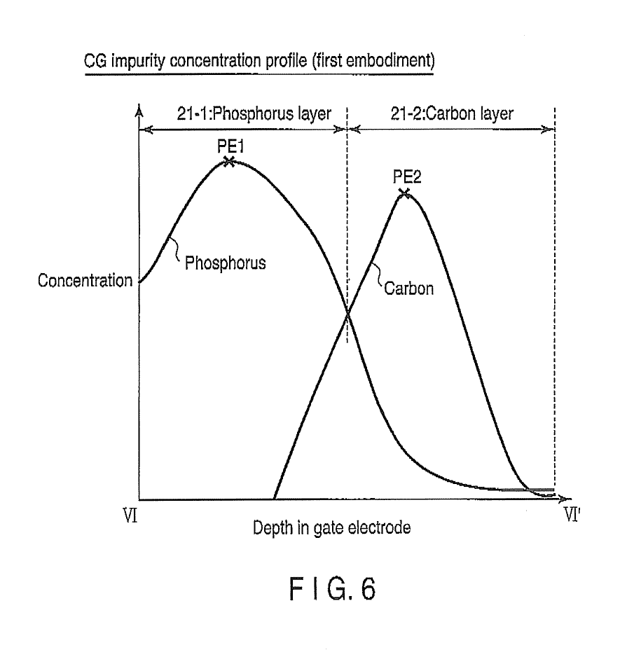

FIG. 6 shows an impurity concentration profile in the depth direction of the gate electrode 21 along line VI-VI′ in FIG. 3.

As shown in FIG. 6, at first, a phosphorus region with a high impurity concentration, which constitutes the phosphorus layer 21-1, is disposed at a shallow position in the gate electrode 21. Then, at a deep position in the gate electrode 21, a carbon region with a high impurity concentration, which constitutes the carbon layer 21-2, is disposed. In this example, the phosphorus concentration peak PE1 is equal to or higher than the carbon concentration peak PE2 (PE1≧PE2). As shown in FIG. 6, the phosphorus layer 21-1 and carbon layer 21-2 do not include only phosphorus and carbon, respectively. The phosphorus layer 21-1 also includes carbon, and the carbon layer 21-2 also includes phosphorus.

### <2. Manufacturing Method>

Next, referring to FIG. 7, FIG. 8 and FIG. 9, a method of manufacturing the semiconductor device according to the first embodiment is described. In the description below, the structure shown in FIG. 5 is described by way of example.

To start with, as shown in FIG. 7, silicon insulation films are buried in trenches which are formed in the silicon substrate 11, and thus device isolation insulation films STI are formed.

Then, in order to perform channel impurity doping for controlling the threshold of the N-type transistor, a photoresist (not shown) is coated and an opening for exposing the N-area is formed in this photoresist. Subsequently, boron for controlling the threshold is doped in the N-area. Then, the photoresist is removed by, e.g. wet etching.

Following the above, in order to perform channel impurity doping for controlling the threshold of the P-type transistor, a photoresist (not shown) is coated and an opening for exposing the P-area is formed in this photoresist. Subsequently, arsenic for controlling the threshold is doped in the P-area. Then, the photoresist is removed by, e.g. wet etching.

Thereafter, a gate insulation film (not shown) is formed on the silicon substrate 11 by, e.g. thermal oxidation. Polysilicon (Poly-Si) is formed on the gate insulation film, and gate electrodes 21, which are mutually connected over the P-area and N-area, are formed.

Subsequently, as shown in FIG. 8, a photoresist 31 is coated on the gate electrode 21, and an opening for exposing the N-area is formed in this photoresist, thereby to perform a gate pre-doping step for controlling the ratio of depletion in the gate electrode 21.

Then, for example, as impurities for making amorphous the gate electrode 21 of the N-type transistor in the N-area, carbon is doped in the gate electrode 21, for example, with 1.0 Key at a concentration of about 3.0E+10 cm⁻². Thereby, the gate electrode 21 can be made amorphous, and the channeling control at the time of implanting a dopant is enabled.

Subsequently, as shown in FIG. 9, in the state in which the gate electrode 21 is made amorphous, phosphorus is doped in the gate electrode 21. Thus, even if a heating process is performed thereafter, the carbon layer 21-2 can suppress diffusion of the doped phosphorus into the P-area. It may be thought that the concentration of phosphorus should be decreased so as to prevent diffusion of phosphorus. However, in this case, the ratio of depletion of the N-type transistor cannot be controlled, and the driving power deteriorates. In this example, there is no need to vary the concentration, and the doped phosphorus can be prevented from diffusing into the P-area.

The photoresist 31 is then removed by wet etching.

Following the above, a region which becomes the gate electrode is covered with a photoresist (not shown), and the gate electrode 21 on the active area is formed in a desired shape by RIE (Reactive Ion Etching). Then, by a post-oxidation process, the damage to the processed gate electrode 21 is remedied. Subsequently, although not shown in the drawings, a MOSFET is fabricated by a manufacturing process which will be described later.

In a subsequent shallow junction formation step of the NMOSFET, an opening is formed in the photoresist in the N-area, and Halo and Extension impurities of the shallow junction are doped. Then, the photoresist is removed by wet etching.

In a subsequent shallow junction formation step of the PMOSFET, an opening is formed in the photoresist in the P-area, and Halo and Extension impurities of the shallow junction are doped. Then, the photoresist is removed by wet etching.

Thereafter, spacers are formed on side walls of the gate electrode 21. Then, deep junctions of the NMOSFET and PMOSFET are formed.

Following the above, silicide layers are formed on the source/drain diffusion layers and gate electrode by a salicide process. Then, a barrier film (Barrier SiN) is formed.

Subsequently, NSG is formed as a PMD (Pre-Medium-Dielectric) film, and the NSG is planarized by CMP (Chemical Mechanical Polishing).

Thereafter, tungsten is buried, a contact plug is formed, a multilayer wiring is formed, and thus the above-described semiconductor device is formed.

In the present embodiment, carbon has been described as an example of impurities which are doped in the gate electrode 21, thereby to make amorphous the gate electrode 21 of polysilicon. However, the impurities are not limited to carbon, and any impurities, which can make polysilicon amorphous, can be used. For instance, xenon or germanium is similarly applicable, and the same advantageous effects can be obtained.

### <3. Advantageous Effects>

According to the semiconductor device of the first embodiment and the method of manufacturing the same, at least the following advantageous effects (1) and (2) can be obtained.

(1) The Operation Margin can Advantageously be Improved.

As has been described above, the semiconductor device according to the first embodiment includes the carbon layer 21-2 which is formed by doping in the gate electrode 21 prior to the doping step of the phosphorus layer 21-1, thereby making the gate electrode 21 amorphous and serving as the layer for suppressing the diffusion of the phosphorus layer 21-1 of the gate electrode 21 into the P-area. In other words, the semiconductor device according to the first embodiment includes, on the semiconductor substrate, the first transistor P2 and second transistor N4 which have the gate electrodes connected to each other, the second transistor N4 having a conductivity type which is different from the conductivity type of the first transistor P2. The gate electrode of the first transistor P2 includes first impurities (phosphorus) and second impurities (carbon) which suppress diffusion of the first impurities. The concentration peak PE1 of the first impurities is set at a shallower position than the concentration peak PE2 of the second impurities.

For example, the impurity concentration profile in the depth direction of the gate electrode 21 is as shown in FIG. 6. As shown in FIG. 6, at first, the phosphorus region with a high impurity concentration, which constitutes the phosphorus layer 21-1, is disposed at a shallow position in the gate electrode 21. Then, at a deep position in the gate electrode 21, a carbon region with a high impurity concentration, which constitutes the carbon layer 21-2, is disposed.

Thus, in the state in which the gate electrode 21 is made amorphous, phosphorus is doped in the gate electrode 21, and the diffusion of phosphorus into the P-area can be suppressed. Thus, even if a heating process is performed thereafter, the carbon layer 21-2 can suppress diffusion of the doped phosphorus into the P-area. Therefore, even in the case of the structure in which the gate electrodes of the N-type transistor and P-type transistor are connected to each other, as in the present embodiment, the diffusion of phosphorus into the P-area can be suppressed.

As a result, the variance of characteristics of P-type transistors (P1, P2) can be suppressed, and the operation margin can advantageously be improved.

(2) The Manufacturing Cost can Advantageously be Reduced.

It may be thought that the concentration of phosphorus should be decreased so as to prevent diffusion of phosphorus. However, in this case, the ratio of depletion of the N-type transistor cannot be controlled, and the driving power deteriorates.

In this embodiment, since there is no need to alter the conditions for fabrication, such as the impurity concentration of phosphorus, the manufacturing cost can advantageously be reduced.

### Second Embodiment

### An Example of Oblique Implantation

Next, referring to FIG. 10, a description is given of a semiconductor device according to a second embodiment and a method of manufacturing this semiconductor device. This embodiment relates to an example of oblique implantation at a tilt angle. A detailed description of the parts common to those of the first embodiment is omitted here.

### <Structure Example>

The structure of the second embodiment differs from that of the first embodiment in that the gate electrode 21 of the N-type transistor does not include the carbon layer 21-2, and the concentration of phosphorus in the gate electrode 21 of the N-type transistor is low in the vicinity of the boundary between the N-area and P-area. In the other structure, the second embodiment is substantially the same as the first embodiment.

### <Manufacturing Method>

Next, referring to FIG. 10, the method of manufacturing the semiconductor device according to the second embodiment is described.

As shown in FIG. 10, like the first embodiment, a photoresist 31 is coated on the gate electrode 21, and an opening for exposing the N-area is formed in this photoresist, thereby to perform a gate pre-doping step for controlling the ratio of depletion in the gate electrode 21.

Then, phosphorus is doped, for example, in the gate electrode 21 in the N-area, e.g. with 2.5 KeV at a concentration of about 6.2E+15 cm⁻², with a tilt angle θ2 being set at about 30°, thus forming a phosphorus layer 21-1.

In this manner, by implanting phosphorus with the tilt angle θ2 being set at about 30°, the concentration of phosphorus in the vicinity of the boundary between the P-area and N-area can be decreased, and the diffusion of doped phosphorus into the P-area can similarly be suppressed.

In the description of the present embodiment, the tilt angle θ2 is set at about 30° by way of example. However, the tilt angle θ2 is not limited to this example. The tilt angle θ2 may be set at any value, if tilt angle θ2 can realize doping of impurities such as phosphorus at a sufficient concentration in the gate electrode 21 of the N-type transistor, and can suppress the diffusion of impurities such as phosphorus into the gate electrode 21 of the neighboring P-type transistor. Specifically, the impurities are implanted from the P-type transistor side, and the tilt angle θ2 is an acute angle to the horizontal direction of the gate electrode.

### <Advantageous Effects>

As has been described above, according to the semiconductor device of the second embodiment and the method of manufacturing the same, at least the same advantageous effects (1) and (2) as described above can be obtained.

Moreover, according to the present embodiment, as illustrated in FIG. 10, phosphorus is doped in the gate electrode 21 with 2.5 KeV at a concentration of about 6.2E+15 cm⁻², with the tilt angle θ2 being set at about 30°, thus forming the phosphorus layer 21-1.

In this manner, by implanting phosphorus with the tilt angle θ2 being set at about 30°, the concentration of phosphorus in the vicinity of the boundary between the P-area and N-area can be decreased, and the diffusion of doped phosphorus into the P-area can similarly be suppressed. Therefore, the manufacturing cost can advantageously be reduced.

Needless to say, this embodiment may be applied in combination with the first embodiment, where necessary.

### Comparative Example

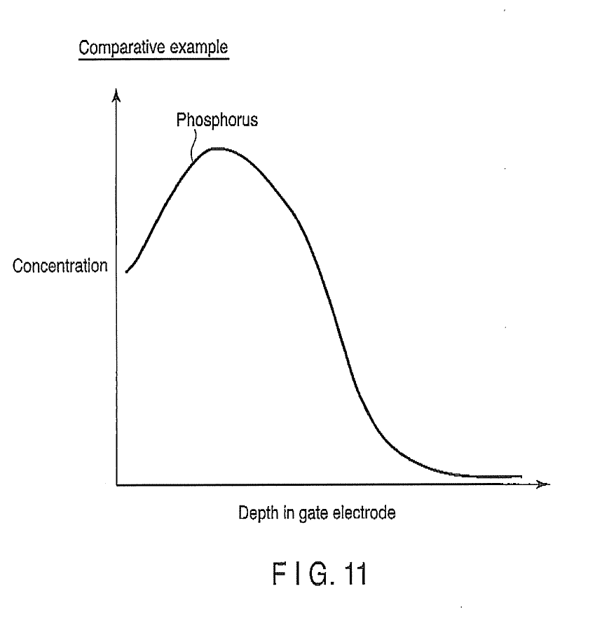

Next, referring to FIG. 11 and FIG. 12, a comparative example is described for the purpose of comparison with the semiconductor devices of the first and second embodiments and the manufacturing methods thereof. A detailed description of the parts common to those of the first embodiment is omitted here.

### <Structure Example>

The semiconductor device of the comparative example differs from the semiconductor device of the first embodiment in that a carbon layer for making the gate electrode amorphous is not disposed in the gate electrode.

Thus, the impurity concentration profile in the depth direction of the gate electrode is as shown in FIG. 11. As shown in FIG. 11, in the comparative example, only a phosphorus region, which constitutes a phosphorus layer, is disposed at a relatively shallow position in the gate electrode 12.

### <Manufacturing Method>

Next, referring to FIG. 12, a description is given of the method of manufacturing the semiconductor device according to the comparative example.

To start with, as shown in FIG. 12, a gate insulation film and a gate electrode 121 (CG: Poly-Si) are successively formed on the device regions AA and device isolation insulation films STI.

Then, a photoresist 131 is coated on the gate electrode 121, and an opening for exposing the N-area is formed in the photoresist 131.

Using the photoresist 131 as a mask, phosphorus 122 is doped in the gate electrode 121 of the N-type MOSFET in a gate pre-doping step, thereby to control the ratio of depletion in the gate electrode 121 of the N-type MOSFET.

However, as shown in FIG. 12, when the phosphorus 122 is doped in the gate electrode 121, the doped phosphorus moves in the gate electrode 121 and diffuses into the P-type MOSFET region (P-area), since the gate electrodes 121 of the N-type MOSFET and P-type MOSFET are connected to each other.

As the result of such diffusion of the phosphorus 122, or impurities, into the gate electrode 121 of the P-type MOSFET, the characteristics of the P-type MOSFET become non-uniform and the operation margin of the SRAM is disadvantageously degraded.

### [Condition for Impurity Doping]

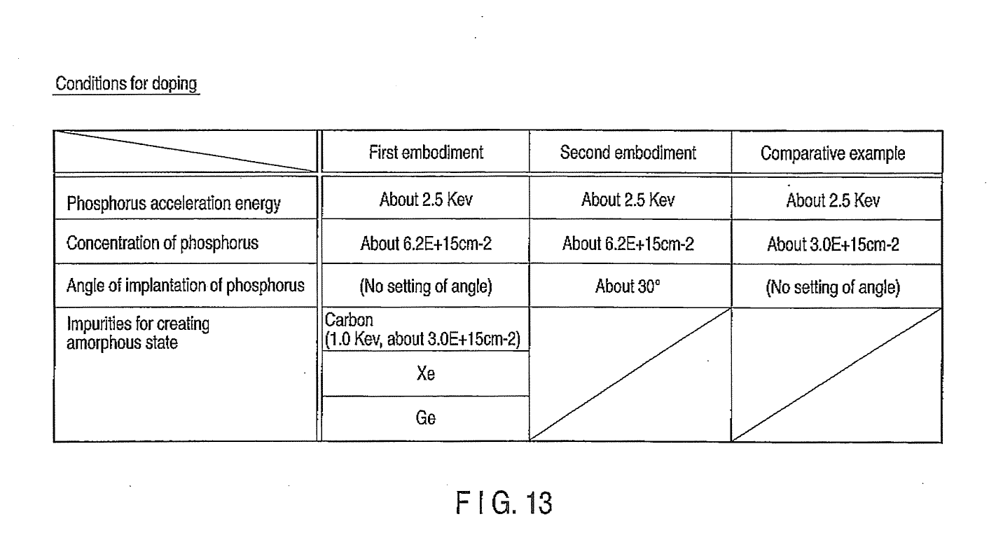

Next, referring to FIG. 13, a description is given of an example of conditions for impurity doping in the above-described first and second embodiment and the comparative example.

As shown in FIG. 13, the acceleration energy for implanting phosphorus is about 2.5 Key, and is common to the first and second embodiment and the comparative example.

The concentration of phosphorus is about 6.2E+15 cm⁻² in each of the first and second embodiments, and is about 3.0E+15 cm⁻² in the comparative example. Specifically, in the comparative example, in order to prevent diffusion of phosphorus into the P-type MOSFET, the concentration needs to be lowered. On the other hand, in the first and second embodiments, phosphorus can be doped at a sufficient concentration.

The angle of implantation of phosphorus (tilt angle) is not set in the first embodiment and the comparative example, and is set at about 30° in the second embodiment.

The impurities, which are doped in order to make the gate electrode amorphous (i.e. in order to suppress diffusion of phosphorus), are carbon, xenon (Xe) or germanium (Ge) in the first embodiment. In this case, the acceleration energy for implanting carbon is about 1.0 KeV, and the impurity concentration is about 3.0E+15 cm⁻².

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first transistor and a second transistor which are disposed on a semiconductor substrate such that a gate electrode of the first transistor and a gate electrode of the second transistor are connected to each other, the first transistor and the second transistor having different conductivity types,
wherein the gate electrode of the first transistor includes first impurities and second impurities which suppress diffusion of the first impurities, and a concentration peak of the first impurities is formed at a shallower position than a concentration peak of the second impurities.

2. The device of claim 1, wherein the first impurities are phosphorus, and
the second impurities are carbon, xenon or germanium.

3. The device of claim 2, wherein the first transistor is an NT-type gate-insulated field-effect transistor,
the second transistor is a P-type gate-insulated field-effect transistor, and
the gate electrode includes polysilicon.

4. The device of claim 1, wherein the second impurities make the gate electrode amorphous, and suppress diffusion of the first impurities through the gate electrode into the second transistor.

5. The device of claim 1, wherein the semiconductor device is an SRAM cell which stores data.

6. The device of claim 5, wherein the SRAM cell comprises:
first and second inverter circuits including the first and second transistors and are connected in a flip-flop fashion so as to store data; and
first and second transfer transistors which transfer the stored data.

7. A method of manufacturing a semiconductor device, comprising:
forming on a semiconductor substrate gate electrodes which are connected to each other over a region of a first conductivity type and a region of a second conductivity type;
doping first impurities in the gate electrode in the region of the first conductivity type, thereby making the gate electrode amorphous; and
doping second impurities in the gate electrode in the region of the first conductivity type in a state in which the gate electrode is made amorphous.

8. The method of claim 7, wherein a concentration peak of the second impurities is formed at a shallower position than a concentration peak of the first impurities.

9. The method of claim 7, wherein the first impurities are carbon, xenon or germanium, and
the second impurities are phosphorus.

10. The method of claim 7, further comprising:
forming a source/drain by doping impurities in the region of the first conductivity type and the region of the second conductivity type, with the gate electrode being used as a mask;
forming spacers on side walls of the gate electrode; and
forming silicide layers on the source/drain and the gate electrode, thereby forming first and second transistors of different conductivity types which are disposed such that gate electrodes of the first and second transistors are connected to each other.

11. The method of claim 10, wherein the first transistor is an N-type gate-insulated field-effect transistor,
the second transistor is a P-type gate-insulated field-effect transistor, and
the gate electrode includes polysilicon.

12. The method of claim 10, wherein the first impurities make the gate electrode amorphous, and suppress diffusion of the second impurities through the gate electrode into the second transistor.

13. The method of claim 10, wherein the semiconductor device is an SRAM cell which stores data.

14. The method of claim 13, wherein the SRAM cell comprises:
first and second inverter circuits which include the first and second transistors and are connected in a flip-flop fashion so as to store data; and
first and second transfer transistors which transfer the stored data.

15. A method of manufacturing a semiconductor device, comprising:
forming on a semiconductor substrate gate electrodes which are mutually connected over a region of a first conductivity type and a region of a second conductivity type;
forming a photoresist on the gate electrode of the second conductivity type;
doping first impurities in the gate electrode of the first conductivity type in such a manner that an angle of implantation to a horizontal direction of the gate electrode, from a direction of the region of the second conductivity type, is an acute angle; and
removing the photoresist.

16. The method of claim 15, further comprising:
forming a source/drain by doping impurities in the region of the first conductivity type and the region of the second conductivity type, with the gate electrode being used as a mask;
forming spacers on side walls of the gate electrode; and
forming silicide layers on the source/drain and the gate electrode, thereby forming first and second transistors of different conductivity types which are disposed such that gate electrodes of the first and second transistors are connected to each other.

17. The method of claim 16, wherein the first transistor is an N-type gate-insulated field-effect transistor,
the second transistor is a P-type gate-insulated field-effect transistor, and
the gate electrode includes polysilicon.

18. The method of claim 16, wherein the semiconductor device is an SRAM cell which stores data.

19. The method of claim 18, wherein the SRAM cell comprises;
first and second inverter circuits which include the first and second transistors and are connected in a flip-flop fashion so as to store data; and
first and second transfer transistors which transfer the stored data.
